(19) United States
(12) Patent Application Publication
(10) Pub. No.: US 2026/0304617 A1
(43) Pub. Date: Oct. 1, 2026

(54) SUBSTRATE

(71) Applicant: KYOCERA CORPORATION, Kyoto-shi, Kyoto (JP)

(72) Inventors: Kouichirou SUGAI, Kyoto-shi (JP); Kenji SUGIMOTO, Kyoto-shi (JP); Yuko IKEUCHI, Kyoto-shi (JP)

(73) Assignee: KYOCERA CORPORATION, Kyoto-shi, Kyoto (JP)

(21) Appl. No.: 19/476,347

(22) PCT Filed: Apr. 8, 2024
(86) PCT No.: PCT/JP2024/014235

§ 371 Date: Oct. 17, 2025

(30) Foreign Application Priority Data
Apr. 18, 2023 (JP) 2023-068000

(51) Int. Cl. H05K 1/09; F04B 53/00; H05K 1/03

(52) U.S. Cl. CPC H05K 1/09; H05K 1/0306; F04B 53/00

(57) ABSTRACT

To provide a substrate that can be used under a condition that at least a portion of an electrode is in contact with a solution containing an electrolyte. The substrate is used under a condition that at least a portion of the electrode is in contact with a solution containing an electrolyte, and includes a ceramic base including a first surface, and an electrode located on the first surface. The electrode includes a conductor layer including an Au layer, and a Pt layer deposited on the conductor layer.

### TECHNICAL FIELD

The present disclosure relates to a substrate used under a condition that at least a portion of an electrode is in contact with a solution containing an electrolyte.

### BACKGROUND OF INVENTION

Various wiring substrates having electrodes (electrode pads) on the surfaces of the substrates have been developed. For example, Patent Document 1 discloses a wiring substrate including a plurality of first pads with copper exposed on the surface thereof and a plurality of second pads with a gold plating layer deposited on the surface thereof.

### CITATION LIST

### Patent Literature

Patent Document 1: JP 6258810 B

### SUMMARY

A substrate according to one aspect of the present disclosure includes a ceramic base including a first surface, and an electrode located on the first surface, in which the electrode includes a conductor layer including an Au layer, and a Pt layer deposited on the conductor layer, and the substrate is used under a condition that at least a portion of the electrode is in contact with a solution containing an electrolyte.

### BRIEF DESCRIPTION OF THE DRAWINGS

FIG. 1 is a schematic cross-sectional view of a pump including a substrate according to Embodiment 1 of the present disclosure.

FIG. 2 is a partial cross-sectional view of the substrate according to Embodiment 1 of the present disclosure.

FIG. 3 is a top view of the substrate according to Embodiment 1 of the present disclosure.

FIG. 4 is a bottom view of the substrate according to Embodiment 1 of the present disclosure.

FIG. 5 is a top view of a substrate according to Embodiment 2 of the present disclosure.

FIG. 6 is a schematic view of a test device and a sample used in a voltage application test.

FIG. 7 is a current-potential curve showing results of LSV measurement.

FIG. 8 is a graph showing changes in current when a voltage is changed by 0.5 V.

FIG. 9 is a graph showing changes in current over time when a constant voltage of 5 Vis applied.

FIG. 10 is a diagram showing measurement points in an electrode portion of a sample.

FIG. 11 is a graph showing results of measuring the thickness of each layer of the sample at each measurement point shown in FIG. 10 over time.

FIG. 12 is a graph showing results of measuring the thickness of each layer of the sample at each measurement point shown in FIG. 10 over time.

### DESCRIPTION OF EMBODIMENTS

When it is assumed that a wiring substrate is used for an actuator pump or the like, it is necessary to consider that at least a portion of an electrode is exposed to a condition that it is in contact with a solution containing an electrolyte.

One aspect of the present disclosure provides a substrate that can be used under a condition that at least a portion of an electrode is in contact with a solution containing an electrolyte.

According to an aspect of the present disclosure, a substrate that can be used under a condition that at least a portion of an electrode is in contact with a solution containing an electrolyte can be implemented.

### Embodiment 1

An embodiment of the present disclosure is described below in detail. In the following description, a distinction between top and bottom is for convenience and does not limit the top and bottom when a substrate is actually used. In this specification, a first surface 21 of a substrate 100 on which an electrode 3 is provided is defined as an upper surface. In the drawings, dimensions of components and dimensional ratios between the components may be different from the actual ones. In particular, the structures of the electrode 3 and an external electrode 5 may be expressed by exaggerating the thickness of each layer in order to facilitate the description of a stacked structure.

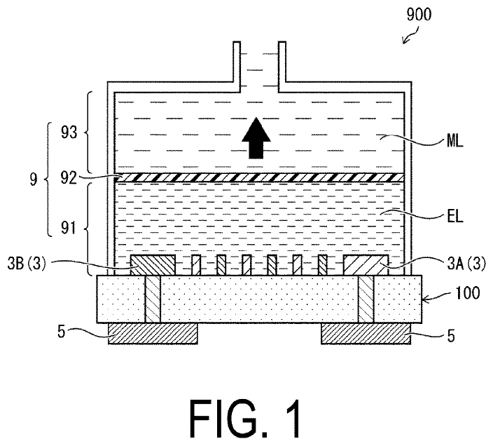

FIG. 1 is a schematic cross-sectional view of a pump 900 including the substrate 100 according to the present disclosure. The substrate 100 according to the present disclosure may be used as a component of the pump 900 as shown in FIG. 1, for example.

The pump 900 includes the substrate 100 including the electrode 3 and a liquid feeding part 9. The liquid feeding part 9 includes a conductive liquid accommodation portion 91 that accommodates a conductive liquid EL, a liquid agent accommodation portion 93 that accommodates a liquid agent ML which is a liquid to be discharged, and a partition wall 92 that is positioned between the conductive liquid accommodation portion 91 and the liquid agent accommodation portion 93. As the conductive liquid EL, for example, a NaCl solution such as physiological saline can be used. The partition wall 92 is made of, for example, silicone rubber or the like, and can propagate the oscillation of the conductive liquid EL to the liquid agent ML.

The pump 900 is an actuator type pump that applies a voltage via an external electrode 5 of the substrate 100 to oscillate the conductive liquid EL and push up the partition wall 92, thereby discharging the liquid agent ML. A voltage applied to the substrate 100 may be approximately 3 V.

When the substrate 100 is used in the application such as the pump 900, at least a portion of the electrode 3 of the substrate 100 is in contact with the conductive liquid EL containing an electrolyte.

### (Configuration of Substrate)

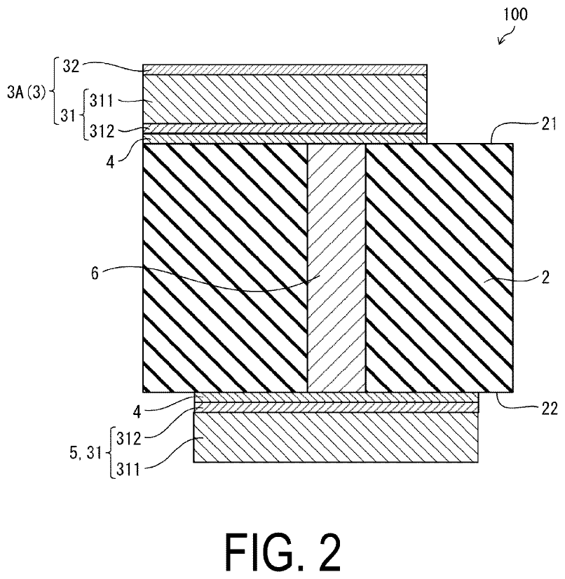

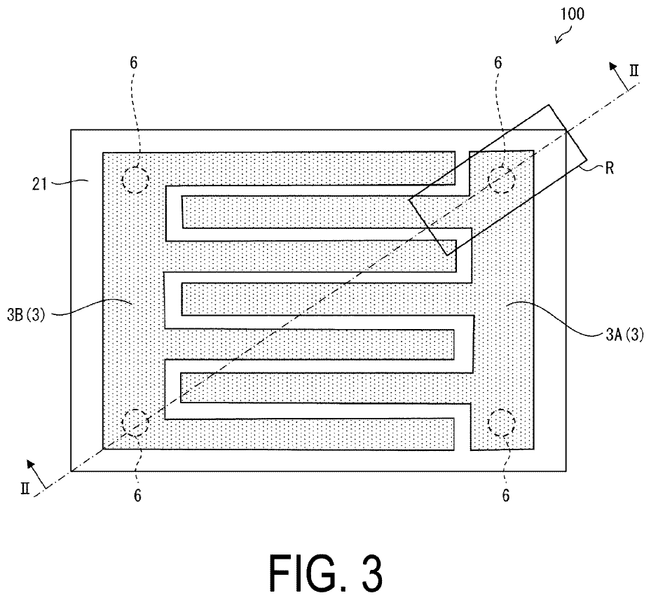

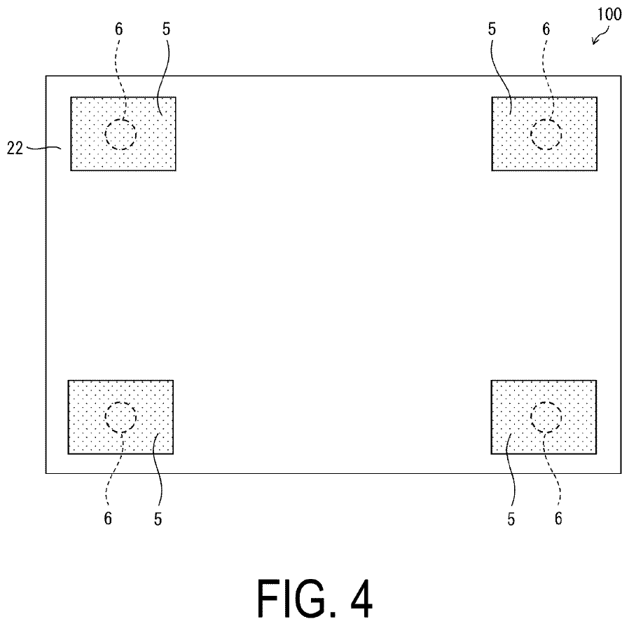

FIG. 2 is a partial cross-sectional view of the substrate 100 according to Embodiment 1. FIG. 3 is a top view of the substrate 100. FIG. 4 is a bottom view of the substrate 100. FIG. 2 shows the cross-section of a region R in FIG. 3.

As shown in FIGS. 2 to 4, the substrate 100 includes a ceramic base 2 including the first surface 21 and a second surface 22 located opposite to the first surface 21, and the electrode 3 located on the first surface 21. The electrodes 3 include an anode 3A and a cathode 3B. A bonding layer 4 may be located between the electrode 3 and the ceramic base 2. The external electrode 5 is located on the second surface 22. The external electrode 5 is electrically connected to the electrode 3 via a through conductor 6.

The ceramic base 2 may be an insulator made of an insulating material containing a ceramic material. For example, the ceramic base 2 may be an insulator made of a ceramic material containing 70 mass % or more of alumina. Alternatively, the ceramic base 2 may be a composite ceramic containing 70 mass % or more of alumina and 5 to 30 mass % of zirconia. The substrate 100 is used under a condition that it is in contact with a solution containing an electrolyte, but in this case, resistance to the solution may be lowered depending on a material. The ceramic base 2 is made of a ceramic material containing 70 mass % or more of alumina, and thus resistance to the solution can be improved. The strength and toughness of the ceramic base 2 can be improved by using a composite ceramic containing zirconia.

The bonding layer 4 is a layer provided to improve the bonding property between the ceramic base 2 and the electrode 3. The thickness of the bonding layer 4 may be 0.01 μm or more and 0.30 μm or less. The bonding layer 4 may be, for example, a Ti layer containing 10 mass % or more of Ti. The Ti layer may be a layer made of Ti. Ti can strengthen bonding between the ceramic base 2 and the metal layer included in the electrode 3, and thus effectively functions as a main component configuring the bonding layer. The bonding layer 4 including the Ti layer can improve the bonding strength between the ceramic base 2 and the electrode 3. When the thickness of the bonding layer 4 is 0.01 μm or more and 0.30 μm or less, the function of the bonding layer 4 can be sufficiently secured.

As shown in FIG. 3, the electrodes 3 may be a pair of comb-shaped electrodes including the anode 3A and the cathode 3B. The structure of the electrode 3 to be described below is common to the anode 3A and the cathode 3B unless otherwise specified. The electrode 3 has a stacked structure including a conductor layer 31 and a Pt layer 32 deposited on the conductor layer 31.

The conductor layer 31 includes an Au layer 311. The Au layer 311 may be a layer containing Au as a main component. Specifically, the Au layer 311 may be a layer containing 98 mass % or more of Au, more preferably 99.99 mass % or more of Au. Alternatively, the Au layer 311 may be a layer made of Au. Au is a metal having a low resistance. The conductor layer 31 includes the Au layer, and thus a high-quality electrode and substrate having a low resistance can be implemented. The overall thickness of the electrode 3 is generally 1.0 μm or more and 3.0 μm or less. The thickness of the Au layer may be, for example, 0.05 μm or more and 2.00 μm or less. The conductor layer 31 includes an Au layer having a thickness of 0.05 μm or more and 2.00 μm or less, and thus a high-quality electrode having a low resistance value can be implemented. When the conductor layer 31 includes a plurality of metal layers, the Au layer may be thicker than the other metal layers. For example, the Au layer 311 may have a thickness three times or more as large as the thickness of the other metal layer included in the conductor layer 31.

The conductor layer 31 may include a second Pt layer 312 positioned in contact with the bonding layer 4. In other words, the conductor layer 31 may include the Au layer 311 and the second Pt layer 312 located between the Au layer 311 and the bonding layer 4. The second Pt layer 312 may be a layer containing Pt as a main component. Specifically, the second Pt layer 312 may be a layer containing Pt in an amount of 98 mass % or more, more preferably 99.9 mass % or more. Alternatively, the second Pt layer 312 may be a layer made of Pt. The second Pt layer 312 is located between the Au layer 311 and the bonding layer 4, and thus the bonding strength between the conductor layer 31 and the bonding layer 4 can be further improved. The thickness of the second Pt layer 312 may be, for example, 0.05 μm or more and 0.50 μm or less. The thickness of the second Pt layer 312 is 0.05 μm or more, and thus the second Pt layer 312 can be easily formed. The thickness of the second Pt layer 312 is 0.50 μm or less, and thus excessive use of Pt, which is expensive, can be curbed.

Alternatively, the conductor layer 31 may include a Pd layer instead of the second Pt layer 312. The Pd layer may be a layer containing Pd as a main component. Alternatively, the Pd layer may be a layer made of Pd. As the same as or similarly to the second Pt layer 312, the Pd layer is also located between the Au layer 311 and the bonding layer 4, and thus the bonding strength between the conductor layer 31 and the bonding layer 4 can be further improved. The thickness of the Pd layer may be, for example, 0.05 μm or more and 0.50 μm or less. The thickness of the Pd layer is 0.05 μm or more, and thus the Pd layer can be easily formed. The thickness of the Pd layer is 0.50 μm or less, and thus excessive use of a noble metal such as Pt, which is expensive, can be curbed.

The Pt layer 32 is a layer located on the outermost layer of the electrode 3. The Pt layer 32 may be a layer made of Pt. Alternatively, the Pt layer 32 may be a layer containing 98 mass % or more of Pt, more preferably 99.9 mass % or more of Pt. The Pt layer 32 is deposited on the conductor layer 31 so as to cover the upper surface of the conductor layer 31. The Pt layer 32 may cover the entire exposed surface of the conductor layer 31. The thickness of the Pt layer may be 0.05 μm or more and 0.50 μm or less.

Under a condition that at least a portion of the electrode 3 is in contact with a solution containing an electrolyte and a voltage equal to or higher than a constant voltage is applied, Au contained in the electrode 3 may be dissolved in the solution by being in contact with the solution. The inventors have found that Pt dissolves very little or does not dissolve in a solution even under the same condition as for Au. For example, when the solution containing the electrolyte is a NaCl solution, the mechanism of dissolution of Au in the solution is estimated to be due to a chemical reaction represented by the following Chemical Formula (1). A test related to the findings will be described in detail in the following section of [Demonstration Test].

2Au+3Cl₂+2HCl→2HAuCl₄ (1)

Since the electrode 3 is configured with the conductor layer 31 and the Pt layer 32 covering the conductor layer 31, a contact area between the Au layer included in the conductor layer 31 and the solution is significantly reduced. Thereby, even when the substrate 100 is used under a condition that at least a portion of the electrode 3 is in contact with a solution containing an electrolyte, dissolution of the metal configuring the electrode 3 can be significantly reduced, and the quality of the substrate can be maintained. Thereby, a substrate that can be stably used under a condition that at least a portion of the electrode 3 is in contact with a solution containing an electrolyte can be implemented. The thickness of the Pt layer 32 is 0.05 μm or more, and thus a thickness necessary for protecting the conductor layer 31 can be secured. The thickness of the Pt layer 32 is 0.50 μm or less, and thus excessive use of Pt, which is expensive, can be curbed.

The external electrode 5 is an electrode to which a potential corresponding to a voltage supplied to the substrate 100 is applied. In Embodiment 1, the substrate 100 includes four external electrodes 5. Two of the four external electrodes 5 are electrically connected to the anode 3A via the through conductors 6, and the remaining two are electrically connected to the cathode 3B via the through conductors 6. In FIGS. 3 and 4, the position of the through conductor 6 is indicated by a dashed line. The four external electrodes may be located at respective corners on the second surface 22 of the ceramic base 2 having a rectangular shape.

The external electrode 5 includes the conductor layer 31. The bonding layer 4 may be located between the external electrode 5 and the ceramic base 2. The bonding layer 4 and the conductor layer 31 may have the same and/or similar configurations as the configurations of the bonding layer 4 and the conductor layer 31 of the electrode 3. On the other hand, the external electrode 5 is located on the second surface 22, and thus is less likely to be in contact with the solution containing the electrolyte. For this reason, the external electrode 5 may not include the Pt layer 32 covering the conductor layer 31. In other words, the external electrode 5 may include the conductor layer 31 including the Au layer 311, and the conductor layer 31 may be formed on the outermost surface and exposed. The outermost layer of the electrode 3 may be an Au layer. Since the external electrode 5 is provided on the second surface 22 opposite to the first surface 21 in contact with the solution, it is not necessary to provide the Pt layer 32 on the outermost layer of the external electrode 5. Thereby, manufacturing costs can be reduced.

### Embodiment 2

Another embodiment of the present disclosure will be described below. For convenience of description, members having the same functions as those of the members described in the above-described embodiment are denoted by the same reference signs, and description thereof is not repeated.

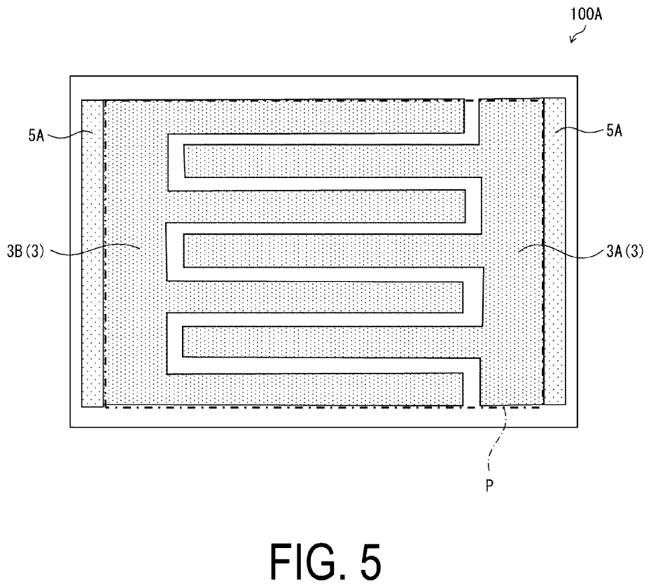

FIG. 5 is a top view of a substrate 100A according to Embodiment 2. As shown in FIG. 5, the substrate 100A differs from that in Embodiment 1 in that an external electrode 5A is located on a first surface 21. The external electrode 5A is located in a region of the first surface 21 that is not in contact with a solvent. For example, in the application of the substrate 100A, a region in contact with a solvent may be within the range of a region P indicated by a chain line in FIG. 5.

The external electrode 5A may be continuously provided adjacent to the electrode 3 as shown in FIG. 5. Alternatively, the external electrode 5A and the electrode 3 may be separated from each other and connected by metallization that enables electrical connection between the external electrode 5A and the electrode 3.

With the configuration of Embodiment 2, the external electrode 5A can be provided on the same surface as the electrode 3. Since the external electrode 5A is located on the first surface 21, the electrode 3 and the external electrode 5A can be connected to each other without the need to provide wiring such as the through conductor 6 inside the ceramic base 2.

The invention according to the present disclosure has been described above based on various drawings and examples. However, the invention according to the present disclosure is not limited to each embodiment described above. That is, the embodiments of the invention according to the present disclosure can be varied in various ways within the scope illustrated in the present disclosure, and embodiments obtained by appropriately combining the technical means disclosed in different embodiments are also included in the technical scope of the invention according to the present disclosure. In other words, a person skilled in the art can easily make various variations or corrections based on the present disclosure. Note that these variations or corrections are included within the scope of the present disclosure.

### [Demonstration Test]

As described above, under a condition that at least a portion of an electrode is in contact with a solution containing an electrolyte, Au contained in the electrode may dissolve in the solution with the application of the voltage. A demonstration test for confirming the dissolution of Au will be described below.

In the demonstration test, a sample S2 having an electrode whose outermost layer is an Au layer and a sample S1 having an electrode whose outermost layer is a Pt layer were used. The electrode of the sample S1 has a film configuration in which a Pt layer is deposited on a Ti layer. An electrode having the configuration of the sample S1 may be referred to as a TiPt electrode for convenience. The electrode of the sample S2 has a film configuration in which an Au layer is deposited on the electrode of the sample S1. An electrode having the configuration of the sample S2 may be referred to as a TiPtAu electrode for convenience.

### (1) Voltage Application Test 1: Constant Potential Measurement

Constant potential measurement was performed using the sample S1 and the sample S2.

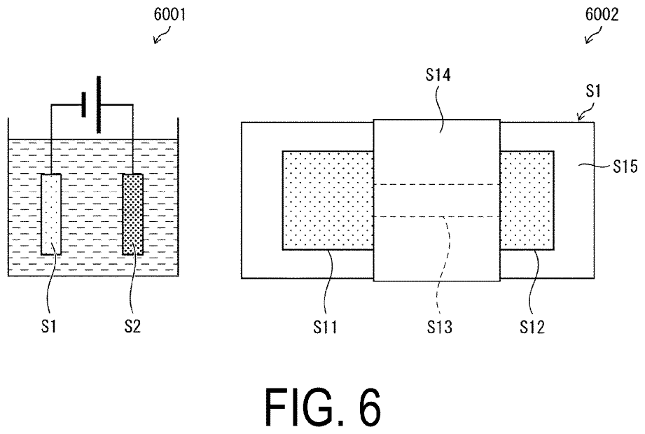

FIG. 6 is a schematic view of a test device and the sample S1 used in a voltage application test. Reference numeral 6001 in FIG. 6 is a schematic view of the test device used in the voltage application test. Reference numeral 6002 in FIG. 6 is a schematic view showing the structure of the sample S1 used in the voltage application test. The sample S1 is configured such that an electrode portion S11 and an external electrode portion S12 are formed on an alumina substrate S15. The external electrode portion S12 is a portion to which a power terminal is connected. The electrode portion S11 and the external electrode portion S12 are electrically connected by a connection portion S13. The connection portion S13 is covered with a masking tape S14. The size of the electrode portion S11 is a square with sides of 10 mm. The electrode portion S11, the external electrode portion S12, and the connection portion S13 all have the same film configuration. The sample S2 has the same configuration as the sample S1 except for the film configuration.

As indicated by reference numeral 6001 in FIG. 6, the electrode portions of the sample S1 and the sample S2 were set to be immersed in a NaCl solution of 0.9 wt %. Power terminals were connected to the respective external electrodes, and a voltage of 6 V was applied. Several seconds after the application of the voltage, bubbles were generated from the electrode portion of the sample S2. After 10 minutes, an Au layer was peeled off (removed) from the outer peripheral portion of the sample S2, and after 30 minutes, the Au layer was peeled off (removed) from the entire surface of the sample. A black precipitate was confirmed in a beaker after the test. On the other hand, no change was observed in the sample S1.

From the above, it was demonstrated that, under a condition that at least a portion of an electrode is in contact with a solution containing an electrolyte, an Au layer included in the electrode changes in the electrode including the Au layer at the outermost layer of the electrode with the application of a voltage.

From the fact that bubbles were generated in the electrode portion of the sample S2, it is estimated that the removal of the Au layer is caused by the dissolution of Au in the solvent by a chemical reaction represented by the following Chemical Formula (1).

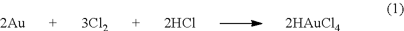

### (2) Evaluation by Potential Sweep (LSV)

Linear sweep voltammetry (LSV) measurements of the sample S1 (TiPt electrode) and the sample S2 (TiPtAu electrode) were performed using a NaCl solution of 0.9 wt %.

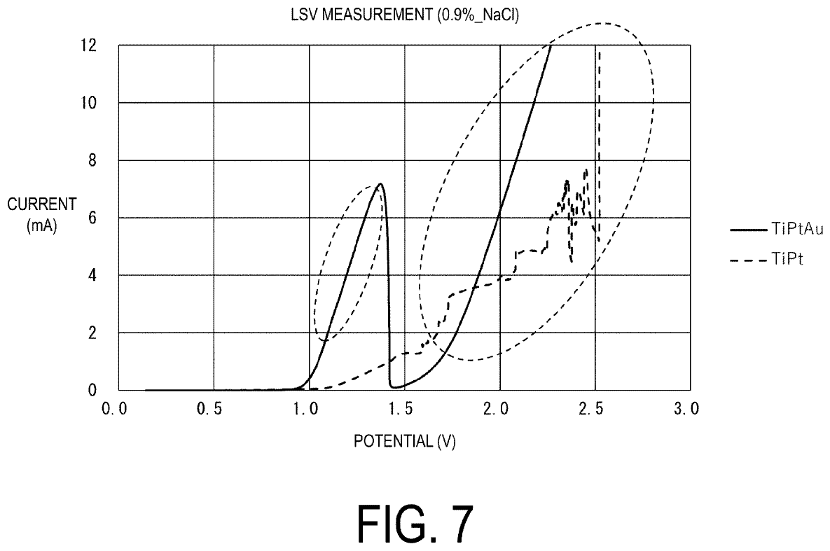

A Pt electrode was used as a counter electrode, and a sweep rate was set to 10 mV/sec. A saturated calomel electrode was used as a reference electrode. FIG. 7 is a current-potential curve showing results of the LSV measurements performed. An alternating dotted-dashed line in a graph indicates a region where bubbles were generated during the test.

In the sample S2, a current was generated from the vicinity of 1 V, and generation of bubbles was confirmed from the counter electrode. Changes in color of the electrode portion were confirmed from the vicinity of 1.2 V.

In the sample S1, a current was generated from the vicinity of 1.8 V, and bubbles were confirmed from the counter electrode. No significant change was confirmed in the color of the electrode portion.

From the above results, it was estimated that a current was generated from the vicinity of 1 V in the sample S2 due to a dissolution current caused by dissolution of an Au film. The generation of a current from just before 2 V occurs in both the sample S1 and the sample S2, and is thus considered to be caused by electrolysis of water.

### (3) Voltage Application Test: Potential Change

For each of the sample S1 (TiPt electrode) and the sample S2 (TiPtAu electrode), changes in current at the time of changing a voltage were measured by using a NaCl solution of 0.9 wt %.

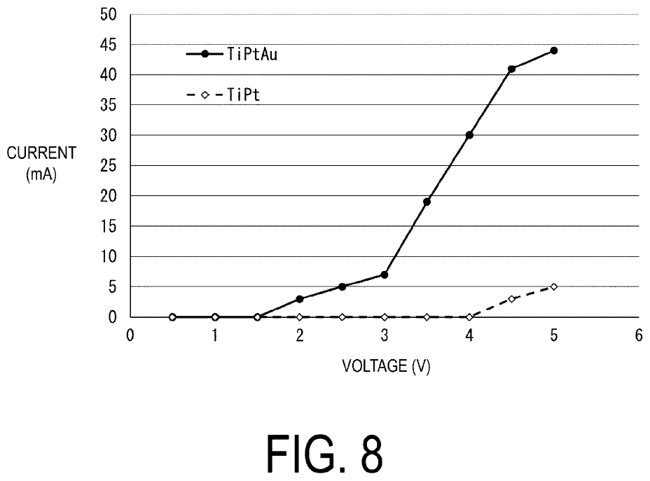

FIG. 8 is a graph showing changes in current when a voltage is changed by 0.5 V. As shown in the graph of FIG. 8, a current was generated from 2 V in the sample S2, and a current was generated from 4.5 V in the sample S1. From this result, the TiPtAu electrode is considered to possibly cause dissolution of a metal configuring the electrode in the solution and generate a dissolution current under a condition that a voltage greater than 1.5 V is applied. For the TiPt electrode, the generation of a current was confirmed in a voltage region higher than 4 V, but the current is estimated not to be a dissolution current.

### (4) Voltage Application Test: Changes Over Time at Constant Voltage

For each of the sample S1 (TiPt electrode) and the sample S2 (TiPtAu electrode), changes in current over time were measured using a NaCl solution of 0.9 wt % when a constant voltage of 5 V was applied.

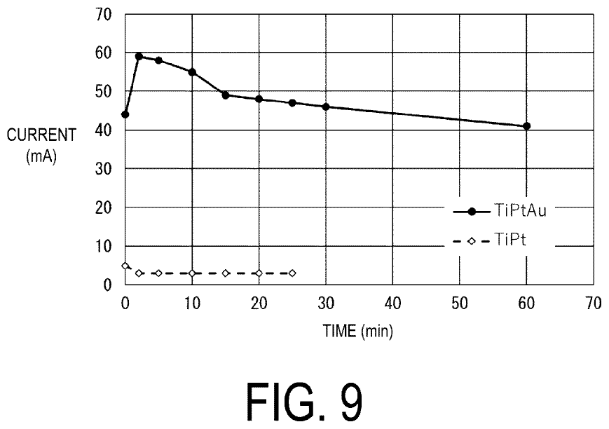

FIG. 9 is a graph showing changes in current over time when a constant voltage of 5 V is applied. As shown in the graph of FIG. 9, when a potential was fixed, a flowing current was larger in the sample S1 than in the sample S2. This result is considered to be a result demonstrating that the metal configuring the electrode is more easily dissolved in the TiPtAu electrode than in the TiPt electrode.

### (5) Voltage Application Test: Changes in Thickness of Electrode Portion Over Time

For each of the sample S1 (TiPt electrode) and the sample S2 (TiPtAu electrode), changes in thickness of the electrode portion over time were measured when a voltage of 6 V was applied in a NaCl solution of 0.9 wt %.

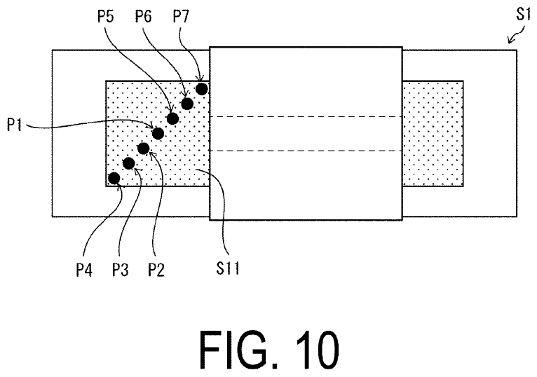

FIG. 10 is a diagram showing measurement points in the electrode portion of the sample S1. The measurement was performed at the same points as in the sample S2.

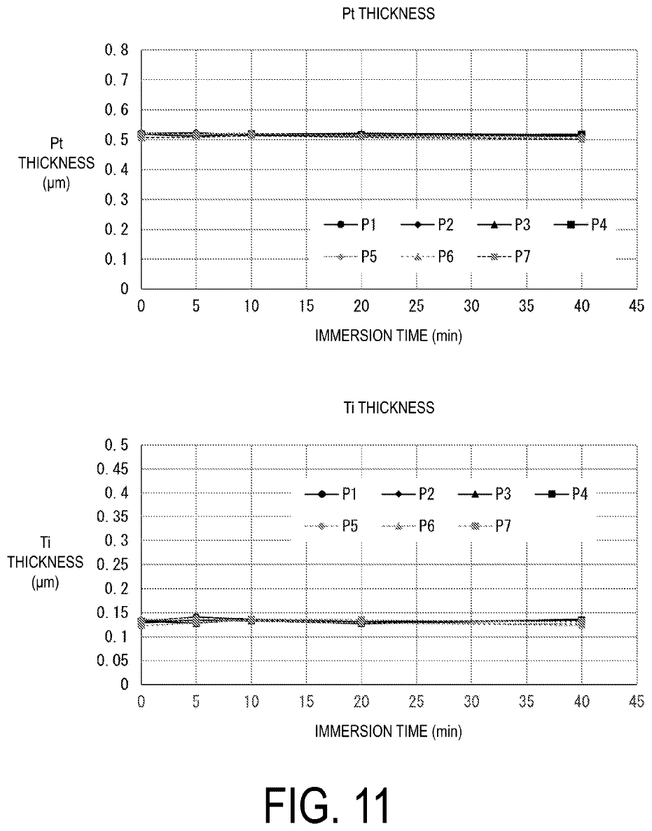

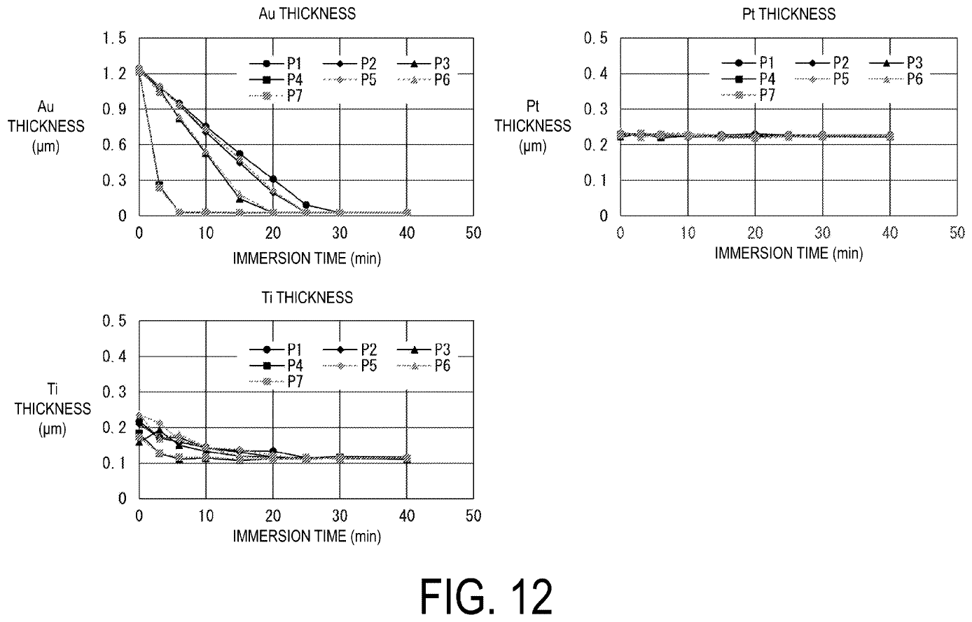

FIG. 11 is a graph showing results of measuring the thickness of each layer of the sample S1 over time at each measurement point shown in FIG. 10. FIG. 12 is a graph showing results of measuring the thickness of each layer of the sample S2 over time at each measurement point shown in FIG. 10.

The thickness of each layer was measured by pulling up the sample from the solution at each measurement time and measuring the thickness of each layer by an X-ray fluorescence method (XRF).

As shown in FIG. 11, the thickness of the sample S1 was not substantially changed at any point during a measurement period of 40 minutes. This result is considered to be a result demonstrating that neither the Pt layer nor the Ti layer configuring the electrode portion was dissolved in the sample S1.

On the other hand, as shown in FIG. 12, a significant change was observed in the thickness of the Au layer of the sample S2 during a measurement period of 40 minutes. In particular, a thickness reduction rate was high in the outer peripheral portion of the electrode portion. It was confirmed that the Au layer was completely dissolved and removed 30 minutes after the start of the measurement. The result of the initial thickness reduction in the Ti layer is considered to be affected by the reduction in the thickness of the Au layer.

From the above results, it was demonstrated that the Au layer of the sample S2 (TiPtAu electrode) was dissolved when a voltage of 6 V was applied in a NaCl solution of 0.9 wt %.

### Effects of Present Disclosure

The substrate 100 according to Embodiment 1 can be used under a condition that at least a portion of an electrode is in contact with a solution containing an electrolyte. The substrate 100 according to Embodiment 1 includes a ceramic base 2 including the first surface 21, and the electrode 3 located on the first surface 21. The electrode 3 includes the conductor layer 31 including the Au layer 311, and the Pt layer 32 deposited on the conductor layer 31.

The above-described demonstration test demonstrated that the Pt layer and the Ti layer are not substantially dissolved even when a voltage is applied under a condition that it is in contact with a solution containing an electrolyte. That is, the substrate 100 includes the Pt layer 32 at the outermost layer of the substrate 100, and thus, even when the substrate 100 is used under a condition that at least a portion of the electrode 3 is in contact with the solution containing the electrolyte, the dissolution of a metal constituting the electrode is significantly reduced, and the quality of the substrate can be maintained. Thereby, a substrate that can be stably used under a condition that at least a portion of an electrode is in contact with a solution containing an electrolyte can be implemented.

The substrate 100 according to Embodiment 1 may be used under a condition that at least a portion of an electrode is in contact with a solution containing an electrolyte and a voltage equal to or higher than 2 V is applied. By the above-described demonstration test, the dissolution of the Au layer was confirmed when a voltage equal to or higher than 2 V was applied under a condition that the TiPtAu electrode was in contact with a solution containing an electrolyte, and thus the electrode may possibly deteriorate under a use condition that a voltage equal to or higher than 2 V is applied. In the substrate 100 according to Embodiment 1, the Pt layer, not the Au layer, is located at the outermost layer of the substrate 100, and thus the substrate 100 can be stably used under a use condition that a voltage equal to or higher than 2 V is applied.

### CONCLUSION

(1) A substrate according to a first aspect of the present disclosure includes a ceramic base having a first surface, and an electrode located on the first surface, wherein the electrode includes a conductor layer including an Au layer, and a Pt layer deposited on the conductor layer, and the substrate is used under a condition that at least a portion of the electrode is in contact with a solution containing an electrolyte.

(2) A substrate according to a second aspect of the present disclosure is the substrate according to the first aspect, further including a bonding layer located between the ceramic base and the electrode.

(3) A substrate according to a third aspect of the present disclosure is the substrate according to the second aspect, in which the bonding layer is a Ti layer containing 10% or more of Ti.

(4) A substrate according to a fourth aspect of the present disclosure is the substrate according to the second or third aspect, in which the conductor layer includes a second Pt layer or a Pd layer that is positioned in contact with the bonding layer.

(5) A substrate according to a fifth aspect of the present disclosure is the substrate according to any one of the first to fourth aspects, in which the Au layer has a thickness of 0.05 μm or more and 2.00 μm or less.

(6) A substrate according to a sixth aspect of the present disclosure is the substrate according to any one of the first to fifth aspects, in which the Pt layer has a thickness of 0.05 μm or more and 0.50 μm or less.

(7) A substrate according to a seventh aspect of the present disclosure is the substrate according to any one of the second to fourth aspects, in which the bonding layer has a thickness of 0.01 μm or more and 0.30 μm or less.

(8) A substrate according to an eighth aspect of the present disclosure is the substrate according to any one of the first to seventh aspects, in which the ceramic base is made of a ceramic material containing 70 mass % or more of alumina.

(9) A substrate according to a ninth aspect of the present disclosure is the substrate according to any one of the first to eighth aspects, in which the ceramic base includes a second surface located opposite to the first surface, and an external electrode electrically connected to the electrode is located on the second surface.

(10) A substrate according to a tenth aspect of the present disclosure is the substrate according to the ninth aspect, in which the external electrode includes a conductor layer including an Au layer, and the conductor layer is exposed.

(11) A substrate according to an eleventh aspect of the present disclosure is the substrate according to any one of the first to eighth aspects, in which an external electrode electrically connected to the electrode is located on the first surface.

(12) A substrate according to a twelfth aspect of the present disclosure is the substrate according to any one of the first to eleventh aspects, wherein the substrate is used under a condition that a voltage equal to or higher than 2 V is applied.

### REFERENCE SIGNS

100, 100A Substrate
2 Ceramic base
3 Electrode
31 Conductor layer
311 Au layer
312 Second Pt layer
32 Pt layer
3A Anode
3B Cathode
4 Bonding layer
5, 5A External electrode
6 Through conductor

1. A substrate comprising:
a ceramic base comprising a first surface; and
an electrode located on the first surface, wherein
the electrode comprises a conductor layer comprising an Au layer, and a Pt layer deposited on the conductor layer, and
the substrate is used under a condition that at least a portion of the electrode is in contact with a solution containing an electrolyte.

2. The substrate according to claim 1, further comprising:
a bonding layer located between the ceramic base and the electrode.

3. The substrate according to claim 2, wherein
the bonding layer is a Ti layer containing 10% or more of Ti.

4. The substrate according to claim 2, wherein
the conductor layer comprises a second Pt layer or a Pd layer located in contact with the bonding layer.

5. The substrate according to claim 1, wherein
the Au layer has a thickness of 0.05 μm or more and 2.00 μm or less.

6. The substrate according to claim 1, wherein
the Pt layer has a thickness of 0.05 μm or more and 0.50 μm or less.

7. The substrate according to claim 2, wherein
the bonding layer has a thickness of 0.01 μm or more and 0.30 μm or less.

8. The substrate according to claim 1, wherein
the ceramic base is made of a ceramic material containing 70 mass % or more of alumina.

9. The substrate according to claim 1, wherein
the ceramic base comprises a second surface located opposite to the first surface, and
an external electrode electrically connected to the electrode is located on the second surface.

10. The substrate according to claim 9, wherein
the external electrode comprises a conductor layer comprising an Au layer, and the conductor layer is exposed.

11. The substrate according to claim 1, wherein
the external electrode electrically connected to the electrode is located on the first surface.

12. The substrate according to claim 1, wherein
the substrate is used under a condition that a voltage equal to or higher than 2 V is applied.
